(19) United States
(12) Patent Application Publication
(10) Pub. No.: US 2002/0098699 A1
(43) Pub. Date: Jul. 25, 2002

(54) METHOD OF FORMING A BIT LINE AND A NODE CONTACT HOLE

(76) Inventors: Horng-Nan Chern, Tainan Hsien (TW); Kun-Chi Lin, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/764,335

(22) Filed: Jan. 19, 2001

(51) Int. Cl. H01L 21/302; H01L 21/461

(52) U.S. Cl. 438/692

(57) ABSTRACT

A first and a second dielectric layer are first formed on a substrate of a semiconductor wafer. A landing pad is then formed in the first dielectric layer, and a plurality of openings used in the formation of the bit lines are formed penetrating from the second dielectric layer through to the surface of the first dielectric layer. A conductive layer is then formed to cover the surface of the semiconductor wafer and filling in the openings in the second dielectric layer. An etching back process is then performed to remove portions of the conductive layer so the surface of the conductive layer is lower than that of the second dielectric layer, and the resulting residual conductive layer within the openings form the bit lines. An etching process is performed to form a passivation recess in the second dielectric layer atop each bit line, followed by the formation of a passivation layer in the passivation recess. A third dielectric layer is then formed on the second dielectric layer and covering the passivation layers on the bit lines. Finally, using the passivation layers as hard masks, the node contact hole is formed within both the second and the third dielectric layer.

### BACKGROUND OF THE INVENTION

1. Field of the Invention

The present invention relates to a method of forming a bit line and a node contact hole, and more particularly, to a method of forming a bit line and a node contact hole using a self-aligned contact (SAC) etching process.

2. Description of the Prior Art

A memory cell in a stacked DRAM is composed of a transistor and a capacitor stacked on the transistor. The transistor is used as a switch in the stacked DRAM, and by controlling a bit line of the DRAM, the data stored in the capacitor can be read out. A storage node of the capacitor is electrically connected with the transistor via a conductive material in a node contact hole. In semiconductor designs, the node contact hole is typically formed in a location penetrating between two bit lines. When the distance between the two bit lines decreases, the conductive material in the node contact hole tends to short circuit the bit lines, and consequently, the data stored in the capacitor may be lost. Thus, the ability to form a node contact to electrically connect with the storage node and provide excellent isolation from the bit lines is important in the improvement of semiconductor processes.

Please refer to FIG. 1 and FIG. 2. FIG. 1 and FIG. 2 are schematic diagrams of a method of forming a bit line 20 and a node contact hole 29 on a semiconductor wafer 10 according to the prior art. As shown in FIG. 1, the semiconductor wafer 10 includes a dielectric layer 14 positioned on the surface of a substrate 12, and a landing pad pit 15 penetrating the dielectric layer 14 to the surface of the substrate 12. In the prior art method, a doped polysilicon layer (not shown) is deposited on the semiconductor wafer 10, and filling the landing pad pit 15. A planarization process is then performed to remove excess portions of the doped polysilicon layer to align the surface of the doped polysilicon in the landing pad pit 15 with the surface of the dielectric layer 14 so as to form a landing pad 16. A dielectric layer 18 is then formed uniformly on the semiconductor wafer 10, and a bit line 20 is formed on the dielectric layer 18. The bit line 20 is composed of a conductive layer 22 and a cap layer 24 stacked on the conductive layer 22, and a spacer is positioned on either sidewall of the bit line 20. The conductive layer 22 includes both a doped polysilicon layer (not shown) used as a main conductive layer, and a silicide layer (not shown) stacked on the conductive layer to reduce the resistance.

As shown in FIG. 2, a dielectric layer 28 is formed on the semiconductor wafer 10 to completely cover the bit line 20. A photolithographic process is then performed to define the patterns of a node contact hole 29 on the surface of the dielectric layer 28, and a self-aligned contact (SAC) etching process is performed to remove portions of both the dielectric layer 28 and the dielectric layer 18 to form a node contact hole 29 penetrating to the surface of the landing pad 16 between the two bit lines 20. A doped polysilicon layer (not shown) is then filled into the node contact hole 29 to form a node contact 30. The node contact 30 electrically connects to an upward storage node of a capacitor (not shown), and to a downward drain of a MOS transistor (not shown) via the landing pad 16 so as to form a data accessing circuit.

The prior art bit line 20 is surrounded by the cap layer 24 and the spacers 26. When the etching process for forming the node contact hole 29 etches to the surface of the spacers 26, the spacers 26 made of silicon nitride can be used as a stop layer, to allow for a greater misalignment tolerance during the etching process and prevent short circuit between the node contact 30 and the conductive layer 22. As well, the conductive layer 22 is isolated from the node contact 30 by the spacers 26 of silicon nitride. However, silicon nitride is a material having a high dielectric constant (about 6-9), and thus should be of limited thickness of silicon nitride under conditions of stress. As a result, the spacers 26 of silicon nitride functions as a good capacitor dielectric layer between the conductive layer 22 and the node contact 30, leading to high couple capacitance and greater leakage currents and thus affecting the electrical performance of the bit lines.

### SUMMARY OF THE INVENTION

It is therefore a primary objective of the present invention to provide a method of forming a bit line and a node contact hole so as to prevent the occurrence of couple capacitance between the bit line and the node contact.

In a preferred embodiment of the present invention, the semiconductor wafer includes a substrate, a first dielectric layer positioned on the substrate, and a second dielectric layer positioned on the first dielectric layer. The first dielectric layer includes a landing pad, and the second dielectric layer includes a plurality of openings that are used in the formation of the bit lines penetrating from the second dielectric layer through to the surface of the first dielectric layer. A conductive layer is first formed to cover the surface of the semiconductor wafer and filling in the openings in the second dielectric layer. An etching back process is then performed to remove portions of the conductive layer so the surface of the conductive layer is lower than that of the second dielectric layer, and the resulting residual conductive layer within the openings form the bit lines. An etching process is performed to form a passivation recess in the second dielectric layer atop each bit line, and a passivation layer is then formed in the passivation recess. A third dielectric layer is then formed on the second dielectric layer and covering the passivation layers on the bit lines. Finally, using the passivation layers as hard masks, the node contact hole is formed within both the second and the third dielectric layers.

It is an advantage of the present invention that the step for the formation of the silicon nitride spacer is not required, and that the passivation layer atop the bit line is used as a hard mask in the SAC etching process to form both the node contact hole, as well as a subsequent spacer made of silicon dioxide on the sidewall of the bit line. Since silicon dioxide has a smaller dielectric constant than that of silicon nitride, the silicon dioxide spacer can be formed of a greater thickness than that of the silicon nitride spacer. As a result, the silicon dioxide spacer in the present invention prevents the occurrence of couple capacitance between the node contact 62 and the bit line 54a and reduce leakage currents.

These and other objectives of the present invention will no doubt become obvious to those of ordinary skill in the art after reading the following detailed description of the preferred embodiment which is illustrated in the various figures and drawings.

### BRIEF DESCRIPTION OF THE DRAWINGS

FIG. 1 and FIG. 2 are schematic diagrams of a method of forming a bit line and a node contact hole on a semiconductor wafer according to the prior art.

FIG. 3 to FIG. 8 are schematic diagrams of a method of forming a bit line and a node contact hole on a semiconductor wafer according to the present invention.

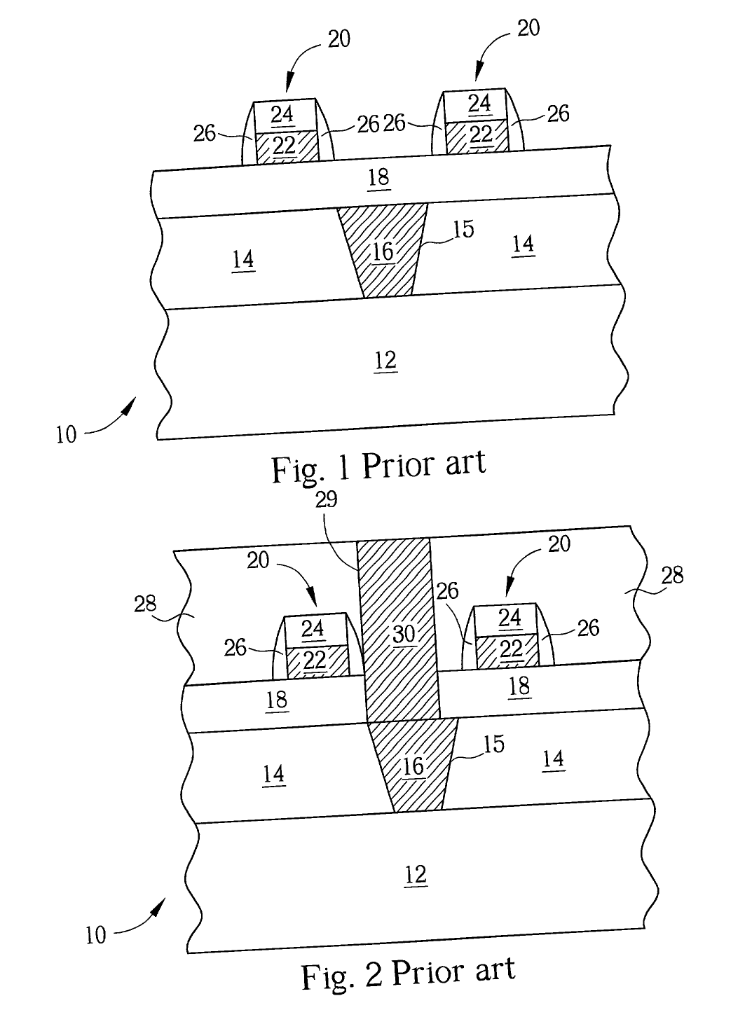

### DETAILED DESCRIPTION OF THE PREFERRED EMBODIMENT

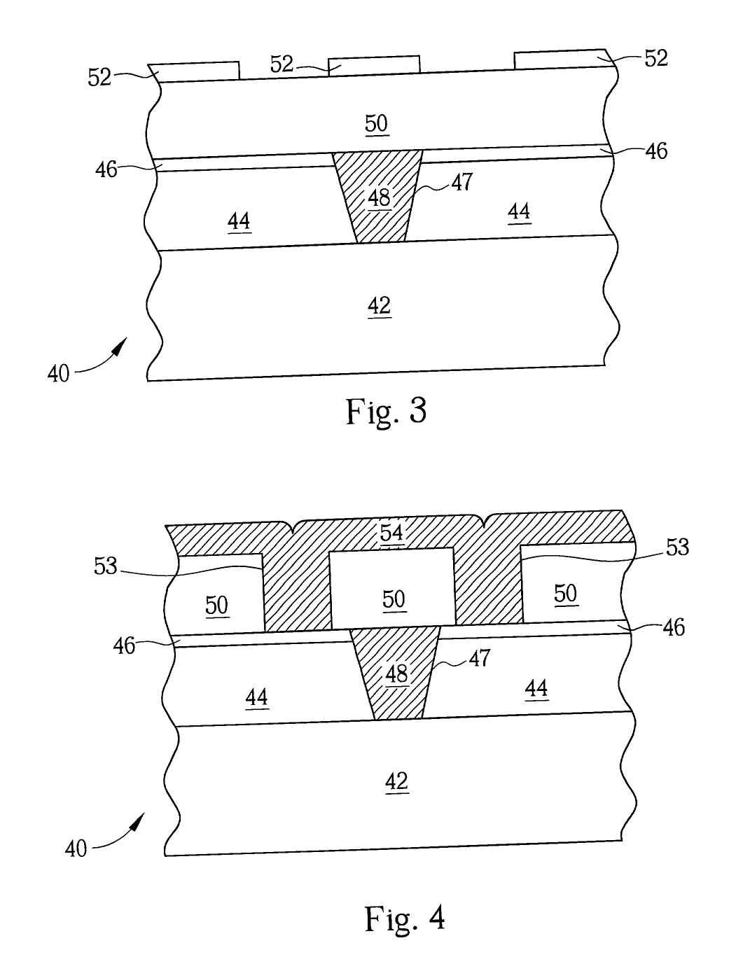

Please refer to FIG. 3 to FIG. 8. FIG. 3 to FIG. 8 are schematic diagrams of a method of forming a bit line 54a and a node contact hole 61 on a semiconductor wafer 40 according to the present invention. As shown in FIG. 3, a thermal oxidation process or a chemical vapor deposition (CVD) process is first performed on the semiconductor wafer 40 to form a dielectric layer 44 of silicon dioxide on the surface of the substrate 42. A CVD process is then performed to form a stop layer 46 of silicon nitride on the dielectric layer 44. A photolithographic process is then performed to define the patterns of a landing pad, followed by an etching process to form a landing pad pit 47 penetrating both the stop layer 46 and the dielectric layer 44 to the surface of the substrate 42. A doped polysilicon layer (not shown) is then formed on the semiconductor wafer 40 and filling the landing pad pit 47. A chemical mechanical polishing (CMP) process is performed to remove portions of the doped polysilicon layer and align the surface of the doped polysilicon layer in the landing pad pit 47 with the surface of the stop layer 46 so as to form a landing pad 48. A dielectric layer 50 is then deposited on the semiconductor wafer 40. The dielectric layer 50 is an inter-poly dielectric (IPD) layer formed of silicon dioxide, and is used to isolate the doped polysilicon layer from the bit lines formed in the subsequent process.

A photoresist layer 52 is formed on the dielectric layer 50, and a photolithographic process is performed to define the patterns of the bit lines on the photoresist layer 52. As shown in FIG. 4, the patterning of the photoresist layer 52 is followed by an etching process. Using the selectivity between the stop layer 46 of silicon nitride and the dielectric layer 50 of silicon dioxide, the etching process is performed to remove portions of the dielectric layer 50 to form openings 53 penetrating the dielectric layer 50 to the surface of the stop layer 46. The opening 53 is used for the formation of the bit line 54a. The photoresist layer 52 is then stripped. A CVD process is performed to deposit a conductive layer 54 on the semiconductor wafer 40, and filling the openings 53. The conductive layer 54 is composed of both a doped polysilicon layer (not shown) used as a main conductive layer, and a silicide layer (not shown) covering the conductive layer to reduce the resistance.

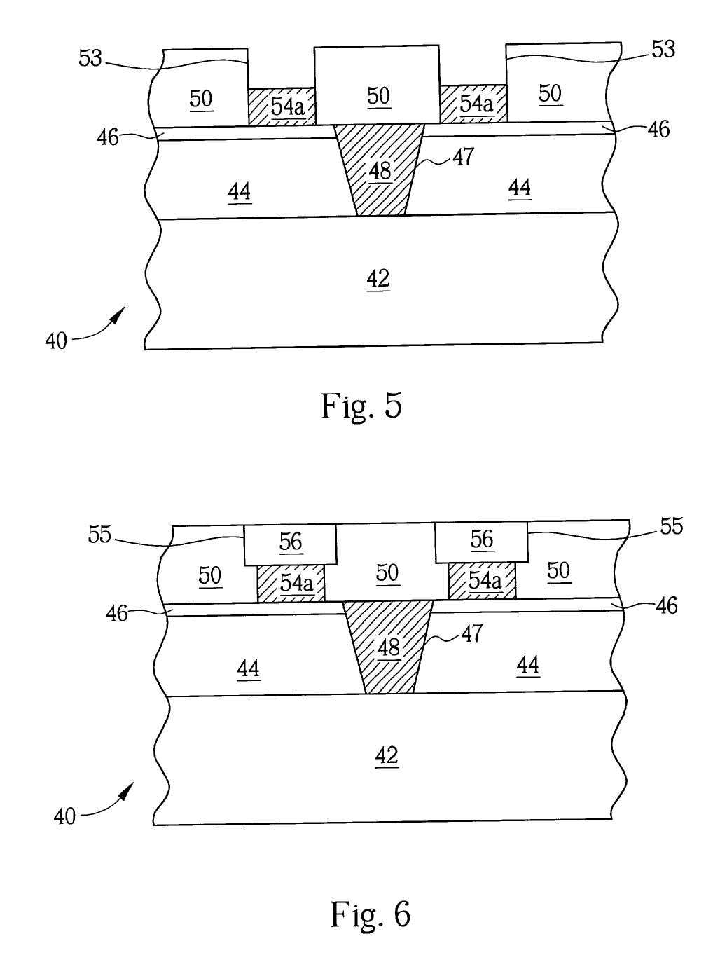

As shown in FIG. 5, a CMP process is performed on the surface of the conductive layer 54 to align the surface of the conductive layer 54 with the surface of the dielectric layer 50. An etching back process is then performed on the conductive layer 54 in the openings 53 to anisotropically remove a 1000 to 1500 angstroms thickness of the conductive layer 54. The thickness of the remaining conductive layer 54 in the openings 53 is about 500 to 2000 angstroms to form a bit line 54a.

As shown in FIG. 6, an isotropic wet etching process is performed to remove portions of the dielectric layer 50 atop the bit line 54a to form a passivation recess 55. The passivation recess 55 has a width greater than that of the bit line 54a. A plasma-enhanced chemical vapor deposition (PECVD) process is then performed to form a silicon nitride layer (not shown) on the dielectric layer 50, and filling the passivation recess 55 to form a passivation layer 56. An etching back process is then performed to remove excess silicon nitride layer to align the surface of the passivation layer 56 with the surface of the dielectric layer 50.

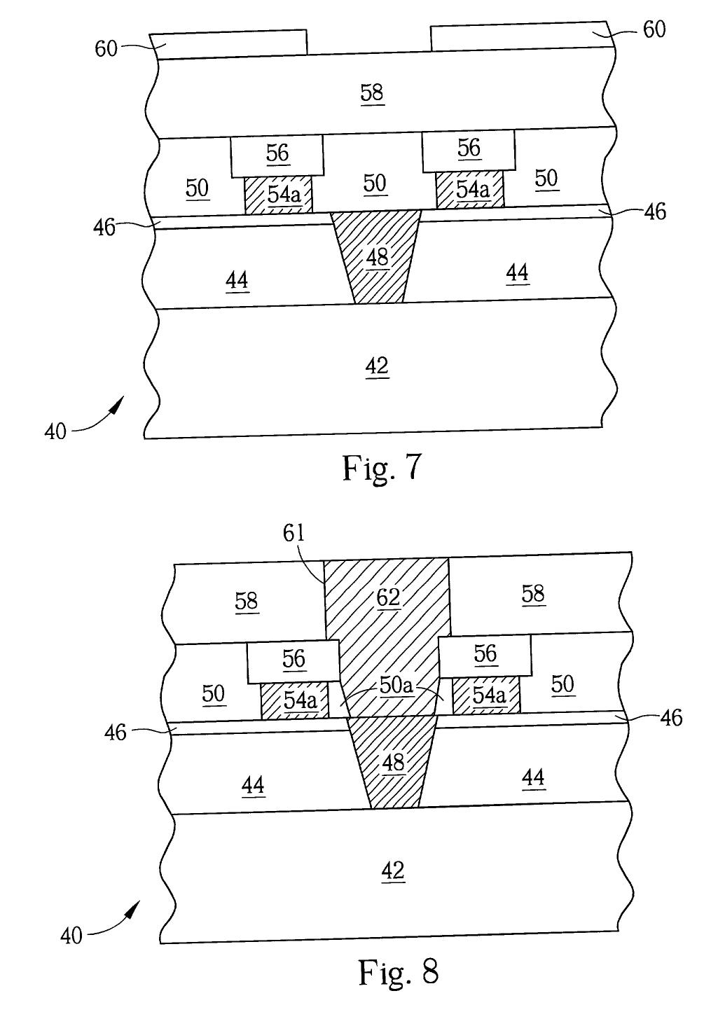

As shown in FIG. 7, a PECVD process is performed to form a dielectric layer 58 of silicon dioxide on both the dielectric layer 50 and on the passivation layer 56. A photoresist layer 60 is then formed on the dielectric layer 58, and a photolithographic process is performed to define the patterns of a node contact hole 61. As shown in FIG. 8, portions of both the dielectric layer 58 and the dielectric layer 50 are removed, following the patterns on the photoresist layer 60. Using the passivation layer 56 as a hard mask, a self-aligned etching process is performed to form the node contact hole 61, between the two bit lines 54a and between the two passivation layers 56, and penetrating the dielectric layer 58 and the dielectric layer 50 to the surface of the landing pad 48 in the dielectric layer 44. Concurrently, the dielectric layer 50 remaining on the sidewall of the bit line 54a in the node contact hole 61 forms spacers 50a made of silicon dioxide.

The photoresist layer 60 is then stripped, followed by the use of both a LPCVD process and an ion implantation process to form a doped polysilicon layer (not shown) filling in the node contact hole 61 so as to form a node contact 62. The node contact 62 electrically connects to an upward storage node of a capacitor (not shown), and to a downward drain of a MOS transistor (not shown) via the landing pad 48 so as to form a data accessing circuit. Finally, a CMP process is performed to align the top of the node contact 62 with the surface of the dielectric layer 58 so as to complete the formation of both the bit line 54a and the node contact 62 in the present invention.

In the present invention method of forming the bit line 54a, couple capacitance occurring between the node contact 62 and the bit line 54a is prevented by removing the step of forming the silicon nitride spacer 26. The present invention first deposits a dielectric layer 50, and then forms both the bit line 54a and the passivation layer 56 atop the bit line 54a in the dielectric layer 50. The subsequent SAC etching process stops on the surface of the passivation layer 56, and the remaining dielectric layer 50 forms a spacer 50a made of silicon dioxide on the sidewall of the bit line 54a. Thus, the present invention utilizes the spacer 50a made of silicon dioxide to function as the dielectric layer between the node contact 62 and the bit line 54a.

In comparison to the prior art method of forming the bit line and the node contact hole, the present invention uses spacers made of silicon oxide to isolate the bit line from the node contact. Since silicon dioxide only has a dielectric constant of about 4 to 4.9, and the thickness of the spacer is decided by the width of the passivation recess atop the bit line, the silicon dioxide spacer is not limited in its thickness as is the case for the prior art silicon nitride spacer under conditions of stress. As a result, a greater thickness of the silicon dioxide spacer can be used. Due to both a lower dielectric constant and a greater thickness of the dielectric layer, the method of the present invention improves the couple capacitance between the bit line and the node contact, as well as to further reduce the leakage currents in the MOS transistor and enhance product yield. As well, a passivation layer made of silicon nitride is formed atop the bit line in the present invention, so the method can also be applied in the SAC etching process for formation of the node contact.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of forming a bit line and a node contact hole on a semiconductor wafer, the semiconductor wafer comprising a substrate, a first dielectric layer positioned on the substrate, a second dielectric layer positioned on the first dielectric layer, and a plurality of openings that are used in the formation of the bit lines and penetrate from the second dielectric layer through to the surface of the first dielectric layer, the method comprising:
forming a conductive layer to cover the surface of the semiconductor wafer and filling in the openings in the second dielectric layer;
performing an etching back process to remove portions of the conductive layer so the surface of the conductive layer is lower than that of the second dielectric layer, and the resulting residual conductive layer within the openings form the bit lines;
performing an etching process to form a passivation recess in the second dielectric layer atop each bit line;
forming a passivation layer in the passivation recess;
forming a third dielectric layer on the second dielectric layer and covering the passivation layers on the bit lines; and
using the passivation layers to protect the bit lines and forming the node contact hole within both the second and the third dielectric layers.

2. The method of claim 1 wherein the method further comprises a chemical mechanical polishing (CMP) process prior to the etching back process.

3. The method of claim 1 wherein the area of the passivation recess opening is larger than the area of the surface of the bit line.

4. The method of claim 1 wherein the etching process is an isotropic etching process.

5. The method of claim 1 wherein the passivation layer is made up of silicon nitride.

6. The method of claim 1 wherein the node contact hole is formed through the third dielectric layer, the second dielectric layer and the first dielectric layer to the surface of the substrate, and makes contact with a source or a drain of a metal-oxide semiconductor (MOS) transistor in the substrate.

7. The method of claim 1 wherein the node contact hole is formed through the third dielectric layer and the second dielectric layer, and makes contact with a landing pad in the first dielectric layer.

8. The method of claim 1 wherein the passivation layer is used as a stop layer in a self-aligned contact (SAC) etching process during the formation of the node contact hole, and the etching process is continually performed on the portions unprotected by the passivation layer.

9. A method of protecting a bit line on a semiconductor wafer, the semiconductor wafer comprising a substrate, a first dielectric layer positioned on the substrate, a plurality of bit lines positioned on the surface of the first dielectric layer, and a second dielectric layer covering both the first dielectric layer and the bit lines, the method comprising:
using a mask to define patterns of a plurality of passivation recesses on the surface of the second dielectric layer, wherein each of the passivation recesses is positioned atop each of the bit lines, and the area of each passivation recess opening is larger than the area of the surface of each bit line;
performing an etching process to form each of the passivation recesses in the second dielectric layer atop each of the bit lines;
forming a passivation layer in the passivation recess;
forming a third dielectric layer on the second dielectric layer and covering the passivation layers within the bit lines; and
using the passivation layers to protect the bit lines and forming the node contact hole in the second dielectric layer and the third dielectric layer.

10. The method of claim 9 wherein the etching process is an isotropic etching process.

11. The method of claim 9 wherein the passivation layer is made up of silicon nitride.

12. The method of claim 9 wherein the node contact hole is formed through the third dielectric layer, the second dielectric layer and the first dielectric layer to the surface of the substrate, and makes contact with a source or a drain of a metal-oxide semiconductor (MOS) transistor in the substrate.

13. The method of claim 9 wherein the node contact hole is formed through the third dielectric layer and the second dielectric layer, and makes contact with a landing pad in the first dielectric layer.

14. The method of claim 9 wherein the passivation layer is used as a stop layer in a self-aligned contact (SAC) etching process during the formation of the node contact hole, and the etching process is continually performed on the portions unprotected by the passivation layer.
